(19) United States
(12) Patent Application Publication
(10) Pub. No.: US 2025/0063696 A1
(43) Pub. Date: Feb. 20, 2025

(54) Automation Device with Heat Sink

(71) Applicant: Siemens Aktiengesellschaft, Muenchen (DE)

(72) Inventors: Ulf STEIN, Schwandorf (DE); Martin BERGMANN, Schnaittenbach (DE)

(21) Appl. No.: 18/802,432

(22) Filed: Aug. 13, 2024

(30) Foreign Application Priority Data
Aug. 17, 2023 (EP) 23191948

(51) Int. Cl. H05K 7/20

(52) U.S. Cl. CPC H05K 7/20418

(57) ABSTRACT

An automation device configured for an automation environment for automating an industrial process includes a housing and a printed circuit board that supports a microprocessor thermally connected with a heat sink that has a plurality of cooling fins each arranged parallel to the printed circuit board with a gap between each other such that, for a first installation position in which the lower side is aligned horizontally, a cooling medium flows from the lower side through the gaps, where the cooling fins have a first, second and third surfaces, and where the second surface is arranged between the first and third surfaces such inclined plane relative to the first and third surfaces is formed and such that, for a second installation position, in which the lower side is aligned vertically, the cooling medium flows over the inclined planes arranged one above the other.

### BACKGROUND OF THE INVENTION

### 1 Field of the Invention

The invention relates to an automation device configured for use in an automation environment for automating an industrial process, having a basic housing comprising a rear side, an upper side, a lower side, a first side part and a second side part that form a box shape, where the rear side is configured for mounting on an assembly structure, a printed circuit board is arranged parallel to the first side part and the second side part at right angles to the upper side or the lower side, and where the printed circuit board supports a microprocessor that is thermally connected with a heat sink that has cooling fins.

### 2. Description of the Related Art

EP 2 736 311 B1 discloses an automation device, which has a basic enclosure, a front hood and a primary heat sink for dissipating heat from a microprocessor.

The miniaturization of electronic components has resulted in the increasing realization of higher packing densities/functional densities of electronic components/parts on a flat wiring module, such as a populated printed circuit board. This leads to an increased power loss, in particular in the case of microprocessors, because the performance of microprocessors is steadily increasing and consequently so also are the thermal losses. For example, the installation of state-of-the-art microprocessors, such as those used for the personal computer sector, in an automation device leads to an enormous increase in the power loss in the automation device.

To date, processors with a lower power density have been used in conventional CPUs throughout the industrial sector. For this reason, heat sinks made from die-cast or extruded parts were previously sufficient as the “state of the art”. Due to the significantly higher power density of the new generation processors, because of its lower cooling capacity such a heat sink would not be sufficient for the environmental conditions required in industry, such as temperatures of up to 60° C., the use of convection cooling only, but no active fans, vibratory and shock loads and very long continuous operation of up to 10 years. Therefore, in future, it will be necessary to use a new much more powerful cooling system in this sector. Furthermore, sufficient cooling will have to be guaranteed regardless of the installation position.

### SUMMARY OF THE INVENTION

It is an object of the invention to provide an improved cooling concept for automation devices via which sufficient cooling is guaranteed regardless of the installation position.

This and other objects and advantages are achieved in accordance with the invention by an automation device in which a heat sink has a plurality of cooling fins that are arranged parallel to the printed circuit board with a gap between each other, and thus for a first installation position in which the lower side is aligned horizontally, it is possible for a cooling medium to flow from the lower side through the gaps, where the cooling fins having a first surface, a second surface and a third surface, where the second surface is arranged between the first and third surfaces such that the second surface forms an inclined plane to the first and third surfaces and thus for a second installation position, in which the lower side is aligned vertically, it is possible for the cooling medium to flow over the inclined planes arranged one above the other.

A continuous inclined “ramp” in the cooling fins now ensures an inclined chimney effect and thus a better coolant flow in the second installation position.

By utilizing the buoyancy of warm air, heated air can flow out easily in accordance with the chimney effect.

The rear side is structured for mounting on an assembly structure, such as a control panel or on a standard top-hat rail. A normal first installation position is a horizontal installation position, but in some cases a second installation position, i.e., an installation position rotated by 90° C. to the first installation position, may be required due to a lack of space.

For example, the design temperature range for automation modules is from 0° C. to +60° C., but 40° C. should not be exceeded in a vertical installation position.

The inclined flow effect via the existing inclined ramps has a further positive effect on the efficiency of any heat pipe used in the vertical case. A positive consequence of this is that cooling performance remains almost constant when a heat pipe is used, even when installed horizontally.

If a heat pipe is used, then the heat sink comprises a cooling plate that is arranged on the microprocessor, where a tube is embedded in the cooling plate such that a first tube section protrudes vertically from the cooling plate, a second tube section is at least partially embedded in the cooling plate and a third tube section in turn protrudes vertically from the cooling plate, and where the cooling fins are arranged on the first tube section and on the third tube section parallel to the printed circuit board with a gap between each other.

The cooling capacity is further improved if a first tube and a second tube are embedded in the cooling plate such that a first tube section of the first tube protrudes vertically from the cooling plate, where a second tube section of the first tube is at least partially embedded in the cooling plate and a third tube section of the first tube in turn protrudes vertically from the cooling plate, and such that a first tube section of the second tube protrudes vertically from the cooling plate, where a second tube section of the second tube is at least partially embedded in the cooling plate and a third tube section of the second tube protrudes vertically from the cooling plate, and where the cooling fins is arranged on the first tube section and on the third tube section of the respective first and second tubes parallel to the printed circuit board with a gap between each other.

For example, two copper pipes, known as heat pipes, can be pressed, glued or soldered into the cooling plate, which acts as a heat spreader. The cooling fins, for example, made of aluminum, can also be either pressed, glued or soldered onto the heat pipes.

To ensure that contact between the microprocessor to be cooled and the cooling plate is not lost even when the automation device is subjected to vibrations, the cooling plate is surrounded by a base support, a cover is arranged on the base support and the printed circuit board is arranged between the base support and the cover, where a resiliently mounted contact pressure structure is arranged between the cover and the printed circuit board.

In order to obtain a stable arrangement of a cooling pack, the cooling fins are formed as stamped sheet metal parts and connecting tabs are arranged in the edge region, where a connecting tab comprising a support part, a first leg and a second leg, the first leg and the second leg is arranged at the edge of the cooling fin, the first and second legs join together to form the support part, a recess is punched out between the first leg and the second leg such that a pin is arranged at the edge, and where a pivot bearing is additionally arranged through the recess at the connection point of the first and second legs to the support part. The connecting tabs are angled at 90 degrees to the surface normal of the cooling fin, making it possible to form a package of cooling fins. The cooling fins can now be stacked and clamp or latch together.

For the purposes of the invention, a heat pipe is therefore understood to be the pipes used of a cooling system, which in the form of a closed system in heat pipes, cools a microprocessor. Most heat pipes work according to a simple system: the thin-walled heat pipe has a special capillary structure on the inside and is made of highly thermally conductive material. It has a small amount of vaporizable liquid. The principle of tube cooling means that a heat pipe absorbs higher temperatures and transports them to a place where the heat can be dissipated.

There is negative pressure inside the heat pipe and there is some liquid inside. This absorbs the heat, heats up and travels in vapor form to the other end of the heat pipe. Due to the low temperature prevailing there, it cools down and thus condenses. This releases the heat, where the liquid then cools once more. Next, it flows back to its original location for heat absorption and readies itself for a new cycle.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The drawing illustrates an exemplary embodiment of the invention, in which:

FIG. 1 is an illustration of an automation device in a three-dimensional view in accordance with the invention;

FIG. 2 is an illustration of a front, side view of the automation device of FIG. 1;

FIG. 3 is an illustration of the automation device of FIG. 2 in an installation position rotated by 90 degrees;

FIG. 4 is a side view of the automation device of FIG. 1;

FIG. 5 is an illustration of the automation device of FIG. 1 with a partially opened enclosure with a view of a heat sink;

FIG. 6 an illustration of the automation device of FIG. 1 with a view of a printed circuit board and a microprocessor;

FIG. 7 is an illustration of a heat sink unit with a cooling fin pack in accordance with the invention;

FIG. 8 is an illustration of a cooling fin in accordance with the invention;

FIG. 9 is an illustration of a cooling unit with a view of a cooling plate and an depiction of heat pipes in accordance with the invention;

FIG. 10 is an illustration of the cooling unit of FIG. 9 in a rotated representation with a view of a cover;

FIG. 11 is an illustration of the cooling unit of FIG. 9 with the cover open and a view of a contact pressure element;

FIG. 12 is an illustration of a contact pressure element in accordance with the invention;

FIG. 13A, FIG. 13B are illustrations of the cooling fin pack for the automation device of FIG. 1 in a horizontal installation position and in a vertical installation position, respectively;

FIG. 14 is a detailed illustration of the cooling fins with interlocking connecting tabs in accordance with the invention;

FIG. 15 is a detailed illustration of a connecting tab in accordance with the invention;

FIG. 16 is an illustration of the cooling fin of FIG. 8 in a sectional view, and

FIG. 17 is an illustration the cooling fin of FIG. 8 in an implementation.

### DETAILED DESCRIPTION OF THE EXEMPLARY EMBODIMENTS

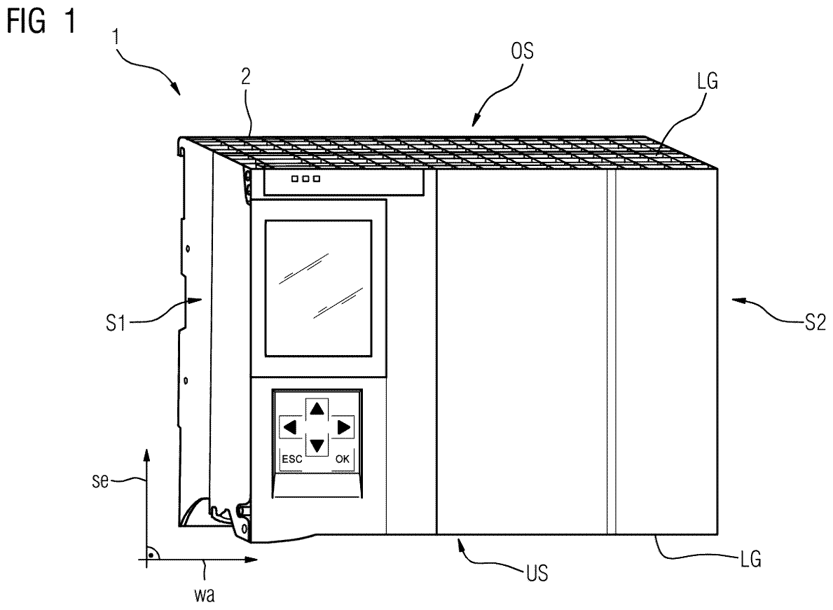

FIG. 1 shows an automation device 1 for use in an automation environment for automating an industrial process.

The automation device 1 has a basic housing 2 comprising a rear side RS, an upper side OS, a lower side US, a first side part S1 and a second side part S2. This gives the automation device 1 the shape of a box, inside which component, such as the electronic circuits, printed circuit board, cooling elements, and/or connections are arranged. The automation device 1 has a ventilation grille LG on the upper side OS and the lower side US. For a standard installation position, the automation device 1 is aligned horizontally WA. This means that the side parts S1, S2 are aligned vertically. In terms of its cooling principle, the automation device 1 is structured for convection cooling, which means that air can flow in from the lower side US, cool the module and then in turn exit on the upper side OS via the ventilation grille LG.

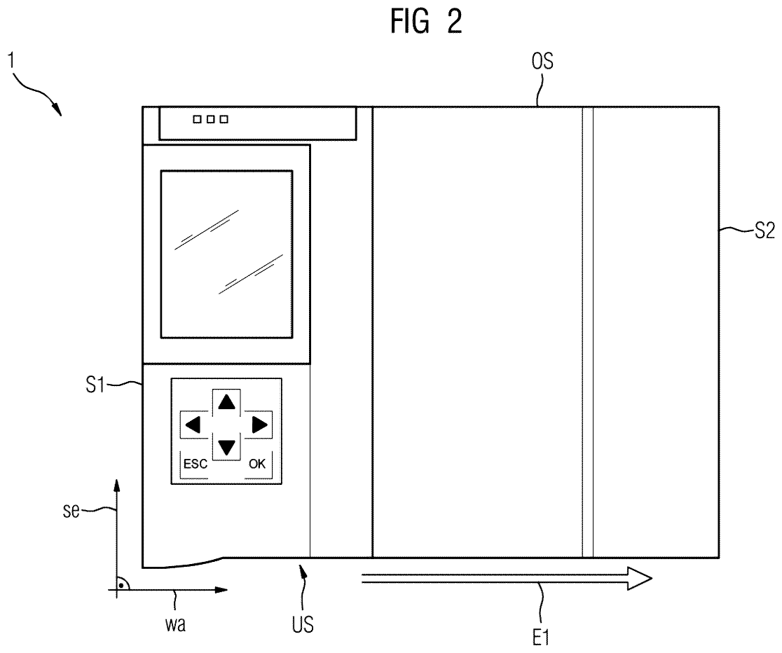

FIG. 2 shows the automation device 1 in a first installation position E1, where the first installation position E1 is a preferred installation position for the automation device 1. The lower side US is aligned horizontally WA.

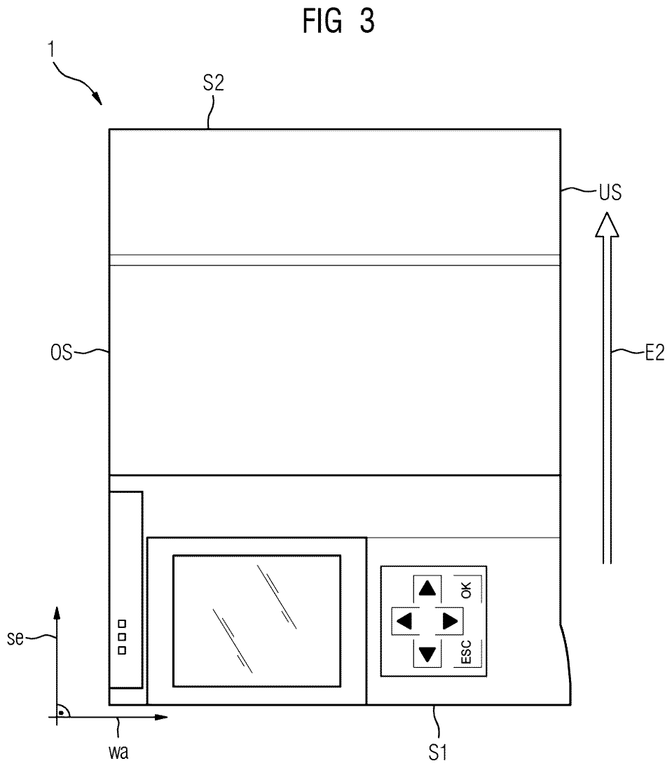

FIG. 3 shows the automation device 1 in a second installation position E2 in which the side parts S1, S2 are aligned horizontally WA and the upper side OS and the lower side US, respectively vertically SE.

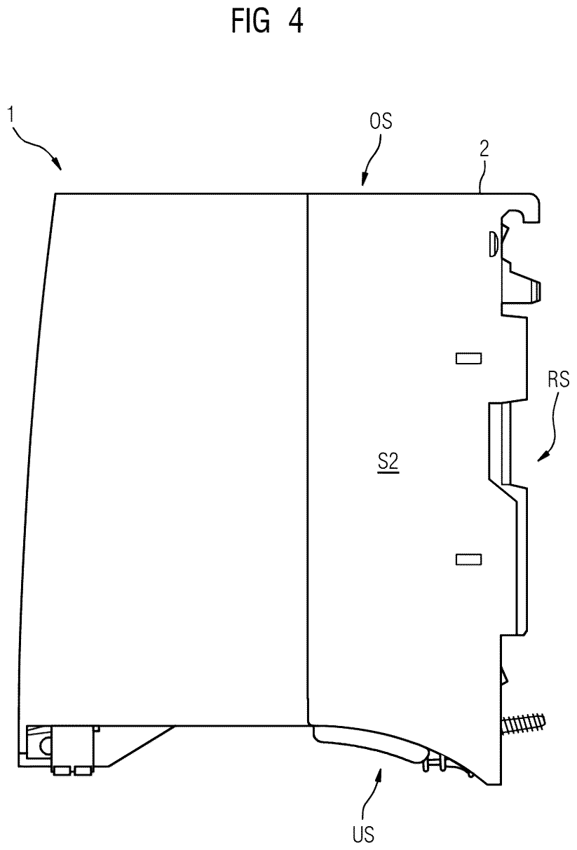

With reference to FIG. 4, the automation device 1 is shown with a view of the second side part S2. The rear side RS is designed for mounting on an assembly structure. Here, for example, there is a hook to hook the automation device 1 onto a profile rail, there is a ground spring to establish ground contact with the profile rail and there is a screw for final fastening.

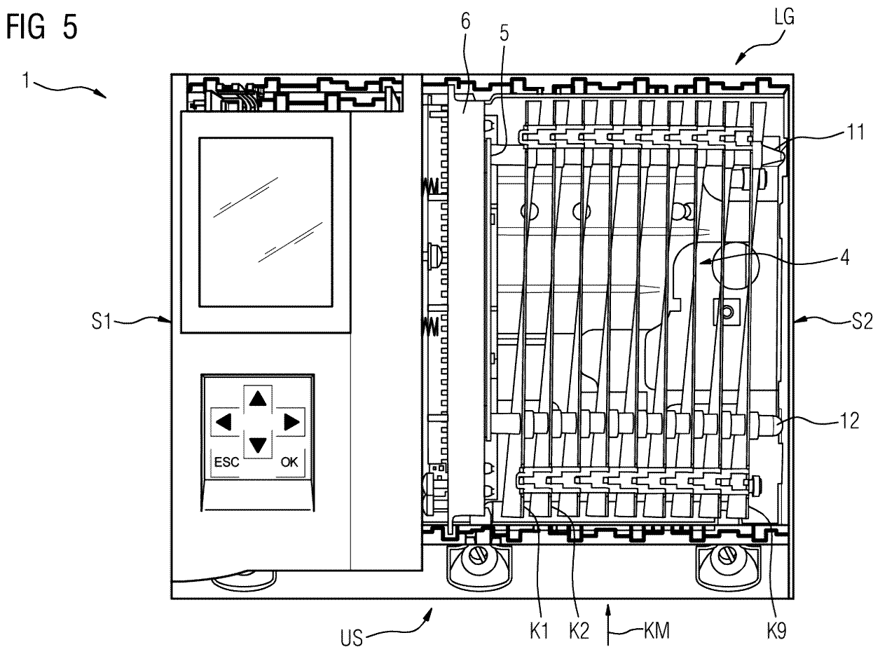

With reference to FIG. 5, the automation device 1 is partially freed from a front hood and a heat sink 4 is visible. The heat sink 4 is thermally connected to a microprocessor 3 arranged on a printed circuit board L. The heat sink 4 has a plurality of cooling fins K1, . . . , K9. The cooling fins K1, . . . , K9 are arranged parallel to the printed circuit board L, with a gap between each other, and thus for the first installation position E1, in which the lower side US is aligned horizontally WA, it is possible for a cooling medium KM to flow from the lower side US through the gaps and to cool the automation device 1. A heat pipe is provided in the heat sink 4 for effective cooling of the cooling plate 5, which rests directly on the microprocessor 3. The heat pipe comprises a first tube 11 and a second tube 12.

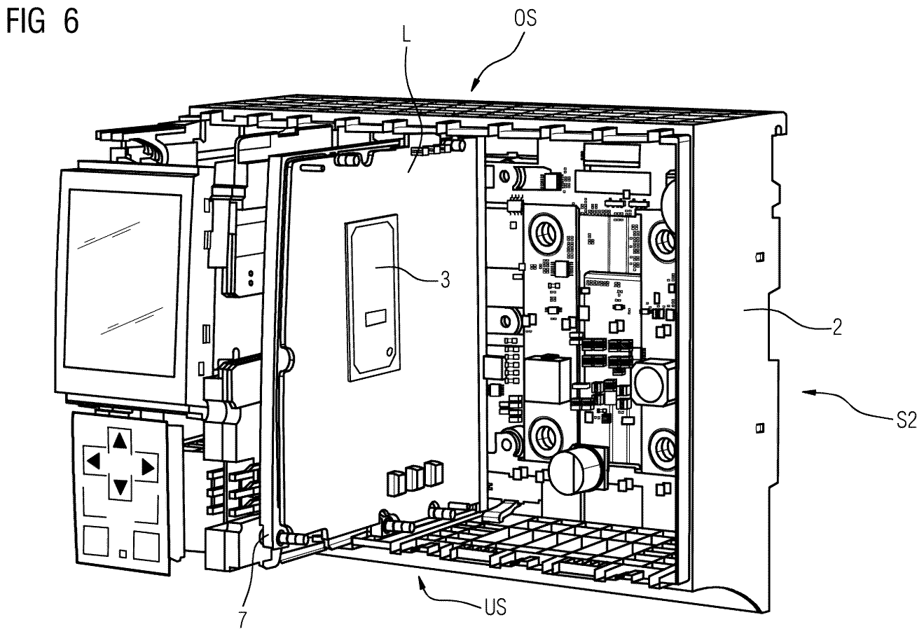

FIG. 6 shows the automation device 1 in a three-dimensional view with the heat sink 4 removed. This reveals a view of the printed circuit board L and the microprocessor 3 installed on it. With conventional processors, the power loss used to be 5 to 12 watts. However, new processors based on a 10 nm manufacturing process are now to be used. These microprocessors achieve a significantly higher clock frequency and therefore also a significantly higher power loss, which must be effectively dissipated. A new type of microprocessor 3, for example, achieves a power loss of almost 50 watts in turbo frequency mode.

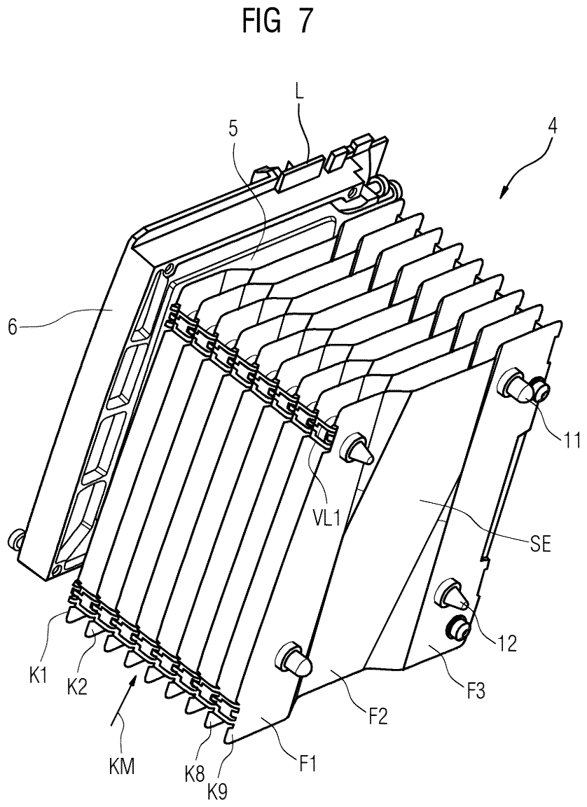

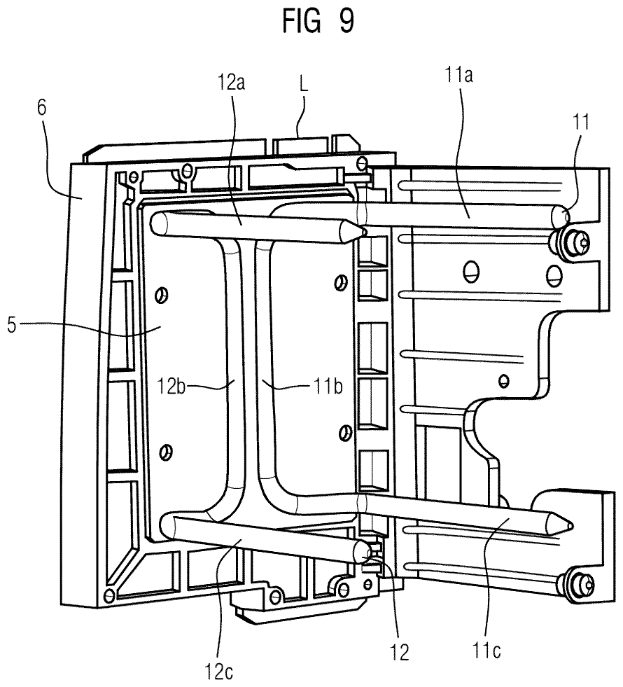

With reference to FIG. 7, the heat sink 4 is shown in a three-dimensional view. The heat sink 4 is arranged on the cooling plate 5. In turn, the cooling plate 5 is arranged directly on the microprocessor 3. A first tube 11 and a second tube 12 (see FIG. 9) are arranged in the cooling plate 5. The heat sink 4 comprises a plurality of cooling fins K1, . . . , K9, which are each arranged parallel to the printed circuit board L with a gap between each other, thus enabling a cooling medium KM to flow in between the cooling fins K1, . . . , K9 from the lower side US.

Continuously inclined ramps are arranged in the cooling fins K1, . . . , K9 to create an inclined chimney effect. A better air flow is achieved, especially in the arrangement, if the heat pipe is aligned vertically upwards. The continuous ramp in the cooling fins is achieved by the cooling fins K1, . . . , K9 having a first surface F1, a second surface F2 and a third surface F3. The second surface F2 is arranged between the first and third surfaces F1, F3 such that the second surface F2 forms an inclined plane SE to the first and third surfaces F1, F3. This arrangement makes it possible for the cooling medium KM to flow over the inclined planes SE arranged one above the other for the second installation position E2, in which the lower side US is aligned vertically. The heated air, for example, can flow out easily in accordance with the chimney effect. The buoyancy of warm air in the direction of flow over the incline is utilized.

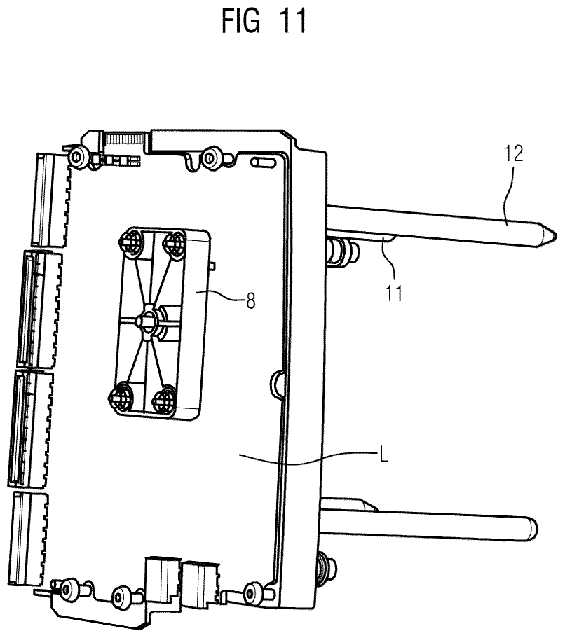

The cooling plate 5 is surrounded by a base support 6. A cover 7 is arranged on the base support 6 (see FIG. 6) and the printed circuit board L is arranged between the base support 6 and the cover 7. A spring-loaded contact pressure means 8 is arranged between the cover 7 and the printed circuit board L (see FIG. 11).

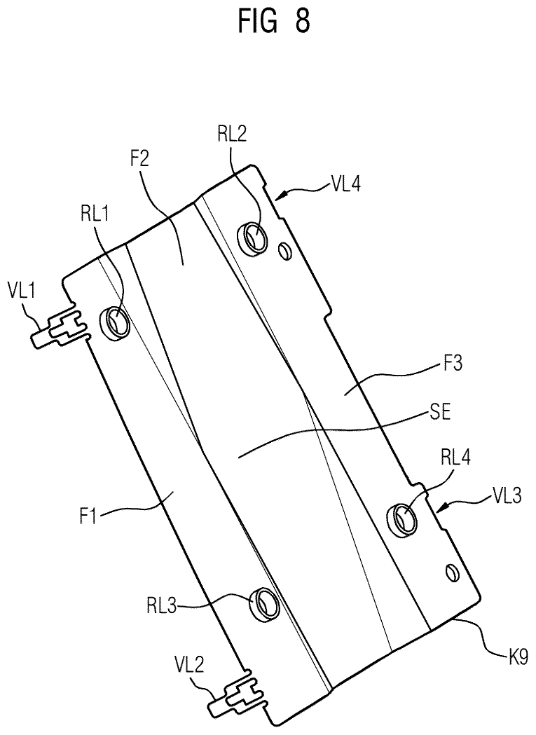

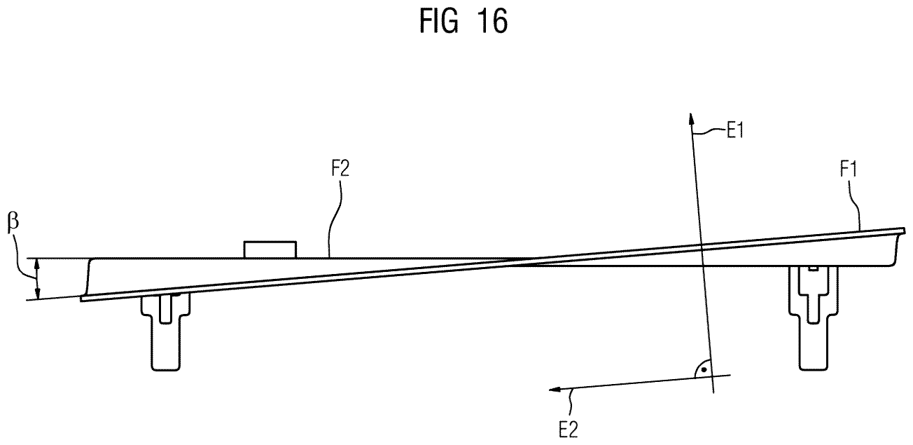

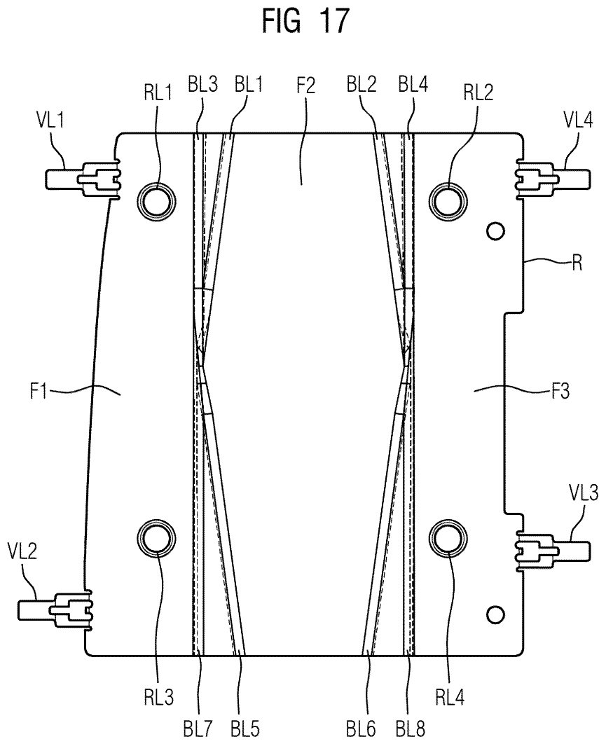

FIG. 8 shows a single cooling fin using the example of the ninth cooling plate K9. The cooling fin with the first surface F1, the second surface F2 and the third surface F3, with the second surface F2 forming an inclined plane SE, is formed by a flat stamped sheet metal part. With regard to the flat stamped sheet metal part (see FIG. 16 and FIG. 17). The second surface F2 is arranged between the first and third surfaces F1, F3 such that the second surface F2 forms the inclined plane SE to the first and third surfaces F1, F3. This inclined plane SE is used for the second installation position E2 for a favorable air flow. This is because, if the lower side US is aligned vertically, it is now possible for the cooling medium KM to flow over the inclined planes SE arranged one above the other.

FIG. 16 shows a cross-section of the cooling fin from FIG. 8. The section goes through the first surface F1 and thus allows a view of the inclined plane SE of the second surface F2, which runs diagonally upwards or diagonally to the left. The second surface F2 has a ramp angle β of approx. 4.5 degrees to the first surface F1. In the first installation position E1, the cooling fin is perpendicular to the first installation position E1 and in the second installation position E2, the cooling fin is horizontal so that the cooling air can flow out via the resulting ramp.

With reference to FIG. 17, the cooling fin is shown as an implementation of the stamped sheet metal part. The connecting tabs can be seen in the edge area of the stamped sheet metal part. Between the first surface F1 and the third surface F3, the second surface F2 is delimited by bending lines BL1, . . . , BL8. The stamped sheet metal part is bent such that the first bending line BL1 forms an upward raised section with the third bending line BL3. The same applies to the opposite side of the first bending line BL1 and the third bending line BL3. The second bending line BL2 and the fourth bending line BL4 are visible here. Here too, the stamped sheet metal part is bent such that the second bending line BL2 is positioned above the fourth bending line BL4 after a bending process. The fifth bending line BL5 and the sixth bending line BL6 are bent downwards, i.e., in the opposite direction to the upper bending lines, so that together the fifth bending line BL5 and the seventh bending line BL7 or the sixth bending line BL6 and the eighth bending line BL8 form a downward sloping ramp. Overall, a ramp running diagonally upwards is achieved by the bending processes in the stamped sheet metal part.

The ninth cooling fin K9 is formed as a stamped sheet metal part made of aluminum and has the connecting tabs VL1, . . . , VL4 in the edge area on the edge R. For attachment to the first tube 11 or the second tube 12, the cooling fin K9 has a first tube hole RL1, a second tube hole RL2, a third tube hole RL3 and a fourth tube hole RL4.

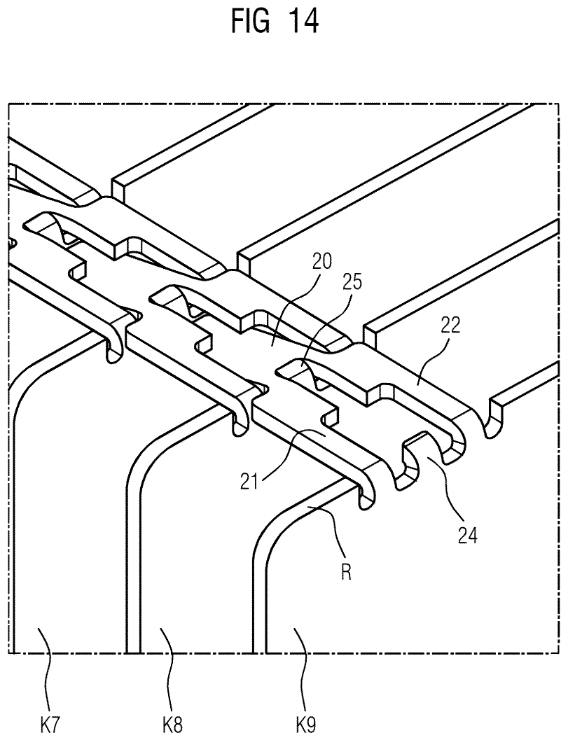

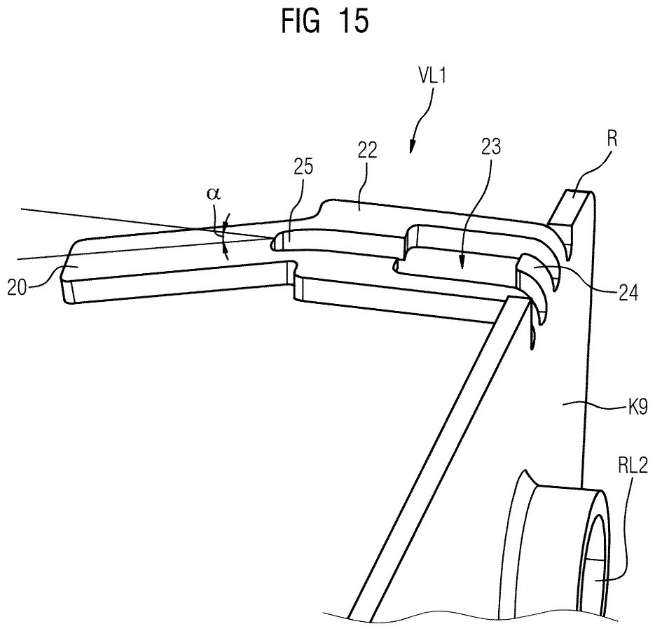

FIGS. 14 and 15 subsequently explain the connecting tabs VL1, . . . , VL4 in detail and show how the configuration of the connecting tabs VL1, . . . , VL4 makes it possible to create a stackable, firmly connected heat sink 4 from the individual cooling fins K1, . . . , K9.

FIG. 9 illustrates the insertion of the first tube 11 and the second tube 12 into the cooling plate 5. The first tube 11 and the second tube 12 are embedded in the cooling plate 5 such that a first tube section 11a of the first tube 11 protrudes vertically from the cooling plate 5. A second tube section 11b of the first tube 11 is at least partially embedded in the cooling plate 5. A third tube section 11c of the first tube 11 in turn protrudes vertically from the cooling plate 5. The second tube 12 is arranged in the same way. A first tube section 12a of the second tube 12 protrudes vertically from the cooling plate 5, while a second tube section 12b of the second tube 12 is at least partially embedded in the cooling plate 5. A third tube section 12c of the second tube 12 in turn protrudes vertically from the cooling plate 5. This arrangement of the first tube 11 and the second tube 12 allows the cooling fins K1, . . . , K9 to be stacked on the vertically protruding tube sections and connected to each other with the connecting tabs VL1, . . . , VL4 to form a heat sink package.

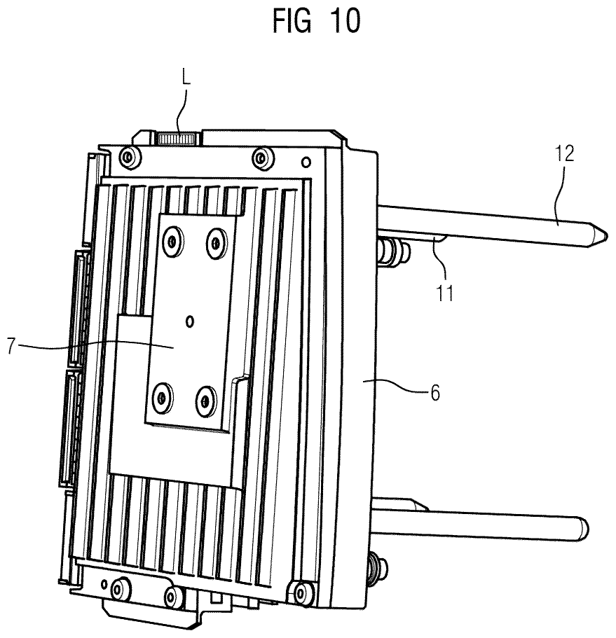

FIG. 10 shows the cover 7 screwed onto the base support 6, where the contact pressure structure 8 is located under the pronounced raised section in the cover 7.

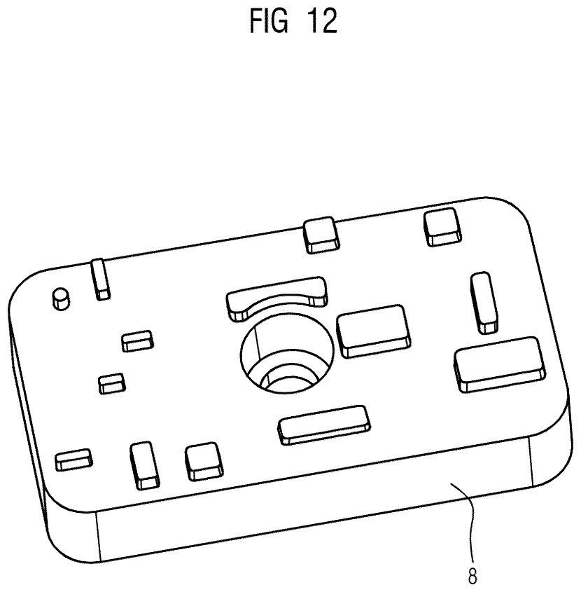

In FIG. 11, the cover 7 is open and the spring-mounted contact pressure means 8 is visible. As shown in FIG. 12, the contact pressure structure 8 is configured to press the printed circuit board L onto the cooling plate 5 in a spring-loaded manner in the cover 7 via certain arranged domes and bars in the contact pressure structure 8, so that the microprocessor 3 always has good contact with the cooling plate 5.

The contact pressure structure 8 is made of a plastic with the abbreviation PEEK 10GF, polyether ether ketone with 10% glass fiber reinforcement. This material can be used at continuous operating temperatures of up to 250-260° C.

The contact pressure structure 8 is formed as a pressure stamp with specially arranged domes that press directly onto the printed circuit board L in the gaps of the assembly. As a result, the printed circuit board L, with the microprocessor 3 fitted on the opposite side of the printed circuit board L, is pressed onto the cooling plate 5 of the heat pipe with a defined force from four pressure springs without damage to electronic components.

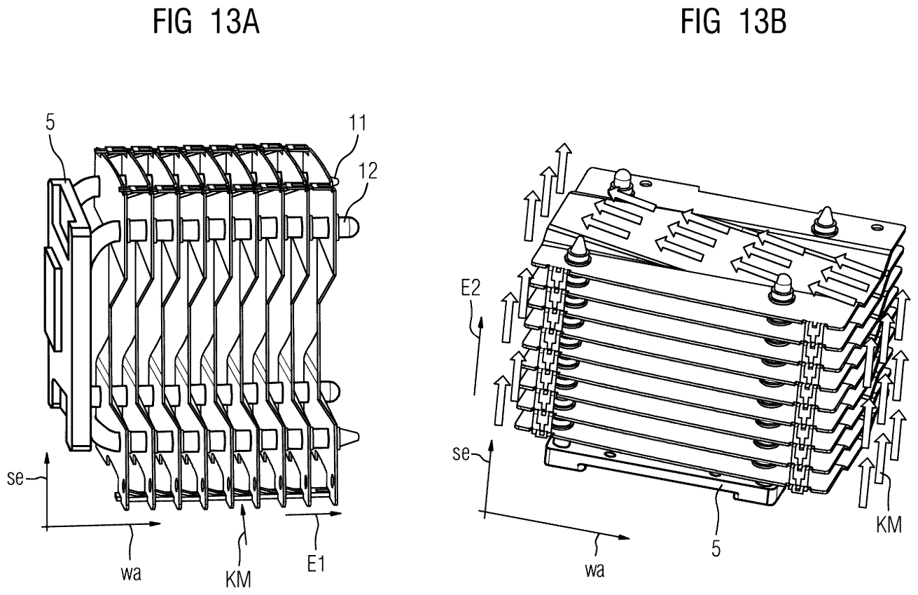

FIGS. 13A and 13B illustrate once again the principle of a heat sink 4 in accordance with the invention, which ensures sufficient cooling of the assembly for a first installation position E1 and a second installation position E2.

As shown in FIG. 13A, a cooling medium KM can flow through the gaps between the cooling fins K1, . . . , K9 in the first installation position E1. In the second installation position E2 illustrated in FIG. 13B, the cooling plate 5 is in a horizontal WA position. It is now possible to improve the flow of the cooling medium KM through the heat sink 4 via a chimney effect due to the stacked inclined planes SE.

FIG. 14 and FIG. 15 show the configuration of the connecting tabs VL1, . . . , VL4. In FIG. 14, a detailed section of the heat sink 4 is shown. The seventh cooling fin K7 is arranged below the eighth cooling fin K8 and below the ninth cooling fin K9. In the edge area at the edge R of the ninth cooling fin K9, the connecting tabs VL1, . . . , VL4 are punched/stamped out of the sheet metal part such that the following arrangement results for a connecting tab VL1. A support part 20 is connected to a first leg 21 and a second leg 22. The first leg 21 and the second leg 22 are arranged on the edge R of the cooling fin K1, . . . , K9. The first and second legs 21, 22 combine to form the support part 20. A recess is punched/stamped out between the first leg 21 and the second leg 22 such that a pin 24 is arranged on the edge R. The counterpart for the pin 24 is also located through the recess 23 at the connection point of the first and second legs 21, 22, where a pivot bearing 25 is arranged for the support part 20. A respective pin 24 of the plate to be hooked engages in the pivot bearing 25 of the cooling fin K1, . . . , K9 thereabove.

The support part 20 not only ensures better or greater strength, but it also defines the gaps between the cooling fins K1, . . . , K9. The sheet metal part in the form of a punched or stamped-out aluminum sheet part is illustrated once again in FIG. 15. The punched-out or stamped-out connecting tab VL1 is bent almost at right angles to the cooling fin K9. Furthermore, the support part 20 is bent again by a bending angle α from the first leg 21 and the second leg 22. This ensure that the support part 20 rests securely on the cooling fin 20 underneath. The second tube hole RL2 shown is also punched or stamped out of the cooling fin K9, with a projection, by a punching or stamping process. This type of punching or stamping makes it easier to glue, solder or press in the first tube 11 or the second tube 12 in place later.

With the connecting tabs VL1, . . . , VL4 shown, a heat sink 4 can be stacked as high as required and always has sufficient strength and always has the same gap.

Thus, while there have been shown, described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements that perform substantially the same function in substantially the same way to achieve the same results are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. An automation device configured for use in an automation environment for automating an industrial process, the automation device comprising:
a basic housing comprising a rear side, an upper side, a lower side, a first side part and a second side part which form a box shape, the rear side being structured for mounting on an assembly; and
a printed circuit board arranged parallel to the first side part and the second side part at right angles to the upper side or the lower side, the printed circuit board supporting a microprocessor which is thermally connected with a heat sink which includes cooling fins;
wherein the heat sink includes a plurality of cooling fins which are each arranged parallel to the printed circuit board with a gap between each other and such that, for a first installation position in which the lower side is aligned horizontally, a cooling medium flows from the lower side through the gaps; and
wherein the cooling fins include a first surface, a second surface and a third surface, the second surface being arranged between the first and third surfaces such that the second surface forms an inclined plane to the first and third surfaces and such that, for a second installation position, in which the lower side is aligned vertically, the cooling medium flows over the inclined planes arranged one above the other.

2. The automation device as claimed in claim 1, wherein the heat sink comprises a cooling plate which is arranged on the microprocessor, a tube being embedded in the cooling plate such that a first tube section protrudes vertically from the cooling plate, a second tube section is at least partially embedded in the cooling plate and a third tube section protrudes vertically from the cooling plate, and the cooling fins being arranged on the first tube section and on the third tube section parallel to the printed circuit board with a gap between each other.

3. The automation device as claimed in claim 1, wherein the heat sink comprises a cooling plate which is arranged on the microprocessor, a first tube and a second tube being embedded in the cooling plate such that a first tube section of the first tube protrudes vertically from the cooling plate, a second tube section of the first tube is at least partially embedded in the cooling plate and a third tube section of the first tube in turn protrudes vertically from the cooling plate, and such that a first tube section of the second tube protrudes vertically from the cooling plate, a second tube section of the second tube is at least partially embedded in the cooling plate and a third tube section of the second tube protrudes vertically from the cooling plate, the cooling fins being arranged on the first tube section and on the third tube section of the respective first and second tubes parallel to the printed circuit board with a gap between each other.

4. The automation device as claimed in claim 2, wherein the cooling plate is surrounded by a base support, a cover is arranged on the base support and the printed circuit board is arranged between the base support and the cover; and wherein a resiliently mounted contact pressure structure is arranged between the cover and the printed circuit board.

5. The automation device as claimed in claim 3, wherein the cooling plate is surrounded by a base support, a cover is arranged on the base support and the printed circuit board is arranged between the base support and the cover; and wherein a resiliently mounted contact pressure structure is arranged between the cover and the printed circuit board.

6. The automation device as claimed in claim 1, wherein the cooling fins are formed as stamped sheet metal parts and connecting tabs are arranged in an edge region;
wherein a connecting tab comprises a support part, a first leg and a second leg, the first leg and the second leg being arranged at the edge of the cooling fin;
wherein the first and second legs join to form the support part, a recess is punched out between the first leg and the second leg such that a pin is arranged at the edge; and
wherein a pivot bearing is additionally arranged through the recess at a connection point of the first and second legs to the support part.

7. The automation device as claimed in claim 2, wherein the cooling fins are formed as stamped sheet metal parts and connecting tabs are arranged in an edge region;
wherein a connecting tab comprises a support part, a first leg and a second leg, the first leg and the second leg being arranged at the edge of the cooling fin;
wherein the first and second legs join to form the support part, a recess is punched out between the first leg and the second leg such that a pin is arranged at the edge; and
wherein a pivot bearing is additionally arranged through the recess at a connection point of the first and second legs to the support part.

8. The automation device as claimed in claim 3, wherein the cooling fins are formed as stamped sheet metal parts and connecting tabs are arranged in an edge region;
wherein a connecting tab comprises a support part, a first leg and a second leg, the first leg and the second leg being arranged at the edge of the cooling fin;
wherein the first and second legs join to form the support part, a recess is punched out between the first leg and the second leg such that a pin is arranged at the edge; and
wherein a pivot bearing is additionally arranged through the recess at a connection point of the first and second legs to the support part.

9. The automation device as claimed in claim 4, wherein the cooling fins are formed as stamped sheet metal parts and connecting tabs are arranged in an edge region;
wherein a connecting tab comprises a support part, a first leg and a second leg, the first leg and the second leg being arranged at the edge of the cooling fin;
wherein the first and second legs join to form the support part, a recess is punched out between the first leg and the second leg such that a pin is arranged at the edge; and
wherein a pivot bearing is additionally arranged through the recess at a connection point of the first and second legs to the support part.
